(19) United States
(12) Patent Application Publication
(10) Pub. No.: US 2007/0175506 A1
(43) Pub. Date: Aug. 2, 2007

(54) THERMOELECTRIC MODULE, METHOD OF FORMING A THERMOELECTRIC ELEMENT, AND METHOD OF THERMOELECTRIC MODULE

(75) Inventors: Yuma Horio, Hamamatsu-shi (JP); Hidetoshi Yasutake, Hamamatsu-shi (JP)

Correspondence Address: DICKSTEIN SHAPIRO LLP, 1177 AVENUE OF THE AMERICAS (6TH AVENUE), NEW YORK, NY, 10036-2714, US

(73) Assignee: YAMAHA CORPORATION, Hamamatsu-shi (JP)

(21) Appl. No.: 11/623,982

(22) Filed: Jan. 17, 2007

(30) Foreign Application Priority Data
Jan. 19, 2006 (JP) 2006-011698

(51) Int. Cl. H01L 35/12; H01L 35/34

(52) U.S. Cl. 136/236.1; 136/201

(57) ABSTRACT

A method of forming thermoelectric elements includes introducing a molten thermoelectric-material in a plurality of holes of a mold, and solidifying the molten thermoelectric-material in the plurality of holes, thereby forming a plurality of thermoelectric elements in the plurality of holes without wafer-slicing process or chip-dicing process.

### BACKGROUND OF THE INVENTION

1. Field of the Invention

The present invention generally relates to a thermoelectric module, a method of forming a thermoelectric element, and a method of forming a thermoelectric module.

Priority is claimed on Japanese Patent Application No. 2006-011698, filed Jan. 19, 2006, the content of which is incorporated herein by reference.

2. Description of the Related Art

All patents, patent applications, patent publications, scientific articles, and the like, which will hereinafter be cited or identified in the present application, will hereby be incorporated by reference in their entirety in order to describe more fully the state of the art to which the present invention pertains.

A thermoelectric module is a device that is configured to convert a temperature difference into an electricity by using Seebeck effect. A typical example of the thermoelectric modules includes first and second ceramic substrates with first and second electrode patterns and an array of thermoelectric elements as microchips that are disposed between the first and second electrode patterns. The array of thermoelectric elements may include p-type and n-type thermoelectric elements, which include at least two elements selected from the group consisting of Bi, Sb, Te, and Se.

As a temperature difference between opposite sides of each of the thermoelectric elements is increased, an electricity or an electric power generated by the thermoelectric element is also increased. It is significant for the thermoelectric module to improve a heat discharge efficiency or a heat exhaustion efficiency of a heat exhaustion side thereof. As a heat quantity transferring the thermoelectric element is increased, an electricity or an electric power generated by the thermoelectric element is also increased. It is also significant for the thermoelectric module to improve an efficiency of endothermic process from a heat source.

The thermoelectric element may be formed in a variety of known methods such as a unidirectional solidification process, a hot press process and a deformation process. In accordance with the unidirectional solidification process, a thermoelectric material is weighted and then melts to prepare a molten thermoelectric material. The molten thermoelectric material is then slowly cooled and solidified while giving the thermoelectric material a temperature gradient. The slow cooling and solidifying process can cause large-sized crystal grains of thermoelectric material. The large-sized crystal grains of thermoelectric material can provide high heat conductivity thereof. High heat conductivity is disadvantageous for the thermoelectric element, thereby preparing a solid of thermoelectric material.

In accordance with the hot press method, the thermoelectric material is weighted and melts to prepare a molten thermoelectric material. The molten thermoelectric material is then gradually solidified to prepare an ingot of thermoelectric material. The ingot of thermoelectric material is then grinded to prepare powders of thermoelectric material. The powders of thermoelectric material are then filled in a mold. Alternatively, the molten thermoelectric material is then rapidly cooled and solidified to prepare flakes or powders of thermoelectric material. The flakes or powders of thermoelectric material are then filled in a mold. The flakes or powders of thermoelectric material are then pressed and sintered in the mold, thereby preparing a solid of thermoelectric material.

In accordance with the deformation process, powders or flakes of thermoelectric material are prepared in the same processes as those of the hot press method. The powders or flakes of thermoelectric material are then hot-rolled to prepare an extruded thermoelectric material. The extruded thermoelectric material is then deformed by a molding method or an ECAP method (Equal-Channel Angular Pressing method), thereby preparing a solid of thermoelectric material.

In each of the above-described methods or processes, the solid of thermoelectric material is obtained. The solid of thermoelectric material is then sliced to prepare wafers. Metal layers are then plated on surfaces of each wafer. Each wafer is then diced to prepare chips as thermoelectric elements. The thermoelectric elements are then disposed between first and second ceramic substrates which have first and second electrode patterns, respectively. The thermoelectric elements are then bonded to the first and second electrode patterns by soldering process, thereby forming a thermoelectric module. The conventional methods of forming the thermoelectric module need a large number of the processes that make it difficult to reduce a manufacturing cost thereof. Particularly, two cutting processes, for example, slicing and dicing processes cause substantial increase in the manufacturing cost of the thermoelectric module. However, the following countermeasures have been proposed.

Japanese Unexamined Patent Application, First Publication, No. 5-283753 discloses a first conventional technique for preparing p-type and n-type thermoelectric elements before the p-type and n-type thermoelectric elements are then buried in through holes of a thermally stable insulator.

Japanese Unexamined Patent Application, First Publication, No. 7-162039 discloses a second conventional technique for preparing p-type and n-type thermoelectric elements before the p-type and n-type thermoelectric elements are then contained in through holes of a molded insulating substrate.

The above-described first and second conventional techniques do not need any jig or gadget for placing thermoelectric elements over the substrate, thereby simplifying assembling process. The above-described first and second conventional techniques also improve electric insulativity between adjacent thermoelectric elements. The above-described first and second conventional techniques further provide increased mechanical strength to the thermoelectric module.

The above-described first and second conventional techniques do need highly accurate processing for embedding the solid thermoelectric elements in through holes of the substrate, while creating the smallest possible gap between the solid thermoelectric elements and inner walls of the through holes. The highly accurate processing may cause substantial increase of the manufacturing cost of the thermoelectric module. Another countermeasure to solve the above-described issues has been proposed.

Japanese Unexamined Patent Application, First Publication, No. 10-321921 discloses a third conventional technique for inserting thermoelectric elements in through holes of a honeycomb insulator while interposing an inorganic adhesive agent or an insulating filler between the thermoelectric elements and inner walls of the through holes. The inorganic adhesive agent or the insulating filler fills the gap between the thermoelectric element and an inner wall of the through hole. The inorganic adhesive agent may be an alkali metal silicate based adhesive. The insulating filler may be a sol-gel glass.

The last-described third conventional technique needs the dicing process for forming the thermoelectric elements and the additional process for interposing the inorganic adhesive agent or the insulating filler between the thermoelectric elements and inner walls of the through holes. The third conventional technique increases the number of necessary processes for forming the thermoelectric module.

In view of the above, it will be apparent to those skilled in the art from this disclosure that there exists a need for an improved method and/or module. This invention addresses this need in the art as well as other needs, which will become apparent to those skilled in the art from this disclosure.

### SUMMARY OF THE INVENTION

Accordingly, it is a primary object of the present invention to provide a method of forming thermoelectric elements.

It is another object of the present invention to provide a method of forming thermoelectric elements that have low heat conductivity.

It is a further object of the present invention to provide a method of forming thermoelectric elements free of wafer-slicing process.

It is a still further object of the present invention to provide a method of forming thermoelectric elements free of chip-dicing process.

It is yet a further object of the present invention to provide a method of forming thermoelectric elements at low manufacturing cost.

It is an additional object of the present invention to provide a method of forming a thermoelectric module.

It is another object of the present invention to provide a method of forming a thermoelectric module including thermoelectric elements that have low heat conductivity.

It is still another object of the present invention to provide a method of forming a thermoelectric module free of wafer-slicing process.

It is yet another object of the present invention to provide a method of forming a thermoelectric module free of chip-dicing process.

It is a furthermore object of the present invention to provide a method of forming a thermoelectric module at low manufacturing cost.

In accordance with a first aspect of the present invention, a method of forming thermoelectric elements may include introducing a molten thermoelectric-material in a plurality of holes of a mold, and solidifying the molten thermoelectric-material in the plurality of holes, thereby forming a plurality of thermoelectric elements in the plurality of holes.

In accordance with a second aspect of the present invention, a method of forming a thermoelectric module may include placing a mold that has a plurality of holes at a position adjacent to a cooler, introducing first and second types of molten thermoelectric-material in the plurality of holes of the mold adjacent to the cooler so that a first one of the plurality of holes is filled with the first type of molten thermoelectric-material and a second one adjacent to the first one of the plurality of holes is filled with the second type of molten thermoelectric-material, solidifying the first and second types of molten thermoelectric-material in the plurality of holes, thereby forming first type and second type thermoelectric elements in the plurality of holes, placing the mold having the first type and second type thermoelectric elements on a first substrate that has a plurality of first electrodes so that two adjacent first type and second type thermoelectric elements of the first type and second type thermoelectric elements are in contact with one of the plurality of first electrodes, and placing a second substrate that has a plurality of second electrodes on the first type and second type thermoelectric elements placed on the first substrate so that the two adjacent first type and second type thermoelectric elements are in contact with two adjacent second electrodes of the plurality of second electrodes.

In accordance with a third aspect of the present invention, a method of forming a thermoelectric module may include placing a first mold that has a first plurality of holes at a position adjacent to a cooler, introducing a first type of molten thermoelectric material in the first plurality of holes of the mold adjacent to the cooler so that the first plurality of holes is filled with the first type of molten thermoelectric-material, solidifying the first type of molten thermoelectric-material in the first plurality of holes thereby forming first type thermoelectric elements in the first plurality of holes, placing a second mold that has a second plurality of holes at the position adjacent to the cooler, introducing a second type of molten thermoelectric-material in the second plurality of holes so that the second plurality of holes is filled with the second type of molten thermoelectric-material, solidifying the second type of molten thermoelectric-material in the second plurality of holes thereby forming second type thermoelectric elements in the second plurality of holes, placing the first type and second type thermoelectric elements on a first substrate that has a plurality of first electrodes so that two adjacent first type and second type thermoelectric elements of the first type and second type thermoelectric elements are in contact with one of the plurality of first electrodes, and placing a second substrate that has a plurality of second electrodes on the first type and second type thermoelectric elements placed on the first substrate so that the two adjacent first type and second type thermoelectric elements are in contact with two adjacent second electrodes of the plurality of second electrodes.

In accordance with a fourth aspect of the present invention, a thermoelectric module may include a first substrate having a plurality of first electrodes, a second substrate having a plurality of second electrodes, and an array of first type and second type thermoelectric elements disposed between the first and second substrates. The first type and second type thermoelectric elements are connected between the plurality of first electrodes and the plurality of second electrodes. Two adjacent first type and second type thermoelectric elements of the first type and second type thermoelectric elements are in contact with one of the plurality of first electrodes. The two adjacent first type and second type thermoelectric elements are also in contact with two adjacent second electrodes of the plurality of second electrodes.

These and other objects, features, aspects, and advantages of the present invention will become apparent to those skilled in the art from the following detailed descriptions taken in conjunction with the accompanying drawings, illustrating the embodiments of the present invention.

### BRIEF DESCRIPTION OF THE DRAWINGS

Referring now to the attached drawings which form a part of this original disclosure:

FIG. 1 is a schematic view illustrating an apparatus for preparing thermoelectric elements in accordance with a first embodiment of the present invention;

FIG. 2A is a plan view illustrating a mold to be used for preparing thermoelectric elements in accordance with the first embodiment of the present invention;

FIG. 2B is a cross sectional elevation view illustrating the mold shown in FIG. 2A;

FIGS. 3A through 3D are cross sectional elevation views illustrating sequential steps involved in a method of forming a thermoelectric module in accordance with the first embodiment of the present invention;

FIG. 4A is a plan view illustrating a step involved in a method of forming a thermoelectric module in accordance with a second embodiment of the present invention;

FIG. 4B is a cross sectional elevation view illustrating the step shown in FIG. 4A;

FIGS. 4C and 4D are cross sectional elevation views illustrating subsequent sequential steps involved in a method of forming a thermoelectric module in accordance with a second embodiment of the present invention;

FIG. 5 is a cross sectional elevation view illustrating the thermoelectric module to be measured in thermoelectric conversion efficiency in accordance with the first and second embodiments of the present invention; and

FIG. 6 is a cross sectional elevation view illustrating the thermoelectric module to be measured in maximum endothermic quantity in accordance with the first and second embodiments of the present invention.

### DETAILED DESCRIPTION OF THE INVENTION

In accordance with a first aspect of the present invention, a method of forming thermoelectric elements may include introducing a molten thermoelectric-material in a plurality of holes of a mold, and solidifying the molten thermoelectric-material in the plurality of holes, thereby forming a plurality of thermoelectric elements in the plurality of holes. The method of forming thermoelectric elements does not carry out wafer-slicing process or chip-dicing process, thereby reducing a manufacturing cost of the thermoelectric elements.

Preferably, the method of forming thermoelectric elements may further include cooling the mold before introducing the molten thermoelectric-material in the plurality of holes of the cooled mold. This may cause rapid cooling and solidification of the molten thermoelectric-material, thereby forming small-sized crystal grains of thermoelectric material. The small-sized crystal grains of thermoelectric material may provide low heat conductivity that is advantageous to the thermoelectric element.

Preferably, cooling the mold may include placing the mold at a position adjacent to the cooler, before introducing the molten thermoelectric-material in the plurality of holes, so that the molten thermoelectric material is rapidly cooled and solidified, thereby forming small-sized crystal grains of thermoelectric material. The small-sized crystal grains of thermoelectric material may provide low heat conductivity that is advantageous to the thermoelectric element.

Preferably, the plurality of holes may include a plurality of through holes. In this case, placing the mold may include placing the mold in contact with the cooler. Thermally engaging the molten thermoelectric-material with the cooler may include contacting the molten thermoelectric-material with the cooler, so that the molten thermoelectric material is rapidly and unidirectionally cooled and solidified to form a crystal structure having a generally uniform crystal orientation.

Preferably, solidifying the molten thermoelectric-material may include unidirectionally solidifying the molten thermoelectric-material so that the plurality of thermoelectric elements includes a crystal structure that has a generally uniform crystal orientation.

Preferably, the method of forming thermoelectric elements may further include introducing a different molten thermoelectric-material in a plurality of different holes of a different mold, and solidifying the different molten thermoelectric-material in the plurality of different holes of the different mold, thereby forming a plurality of different thermoelectric elements in the plurality of different holes of the different mold.

Preferably, the plurality of holes of the mold may include first and second sub-pluralities of holes. The molten thermoelectric-material may also include first and second types of molten thermoelectric material. In this case, introducing the molten thermoelectric-material may include placing a first mask on the mold so that the first mask covers the second sub-plurality of holes, introducing the first type of molten thermoelectric material into the first sub-plurality of holes, removing the first mask from the mold, placing a second mask on the mold so that the second mask covers the first sub-plurality of holes, and introducing the second type of molten thermoelectric material into the second sub-plurality of holes. Solidifying the molten thermoelectric-material may also include solidifying the first type of molten thermoelectric material in the first sub-plurality of holes, and solidifying the second type of molten thermoelectric material in the second sub-plurality of holes.

In accordance with a second aspect of the present invention, a method of forming a thermoelectric module may include placing a mold that has a plurality of holes at a position adjacent to a cooler, introducing first and second types of molten thermoelectric-material in the plurality of holes of the mold adjacent to the cooler so that a first one of the plurality of holes is filled with the first type of molten thermoelectric-material and a second one adjacent to the first one of the plurality of holes is filled with the second type of molten thermoelectric material, solidifying the first and second types of molten thermoelectric material in the plurality of holes, thereby forming first type and second type thermoelectric elements in the plurality of holes, placing the mold having the first type and second type thermoelectric elements on a first substrate that has a plurality of first electrodes so that two adjacent first type and second type thermoelectric elements of the first type and second type thermoelectric elements are in contact with one of the plurality of first electrodes, and placing a second substrate that has a plurality of second electrodes on the first type and second type thermoelectric elements placed on the first substrate so that the two adjacent first type and second type thermoelectric elements are in contact with two adjacent second electrodes of the plurality of second electrodes. The method of forming a thermoelectric module does not carry out wafer-slicing process or chip-dicing process, thereby reducing a manufacturing cost of the thermoelectric module. The method of forming a thermoelectric module does not use any jig or gadget to dispose an array of thermoelectric elements between the first and second substrates, thereby further reducing the manufacturing cost of the thermoelectric module.

Preferably, solidifying the molten thermoelectric-material may include thermally engaging the molten thermoelectric-material with the cooler.

Preferably, the plurality of holes may include a plurality of through holes. In this case, placing the mold may include placing the mold in contact with the cooler. Thermally engaging the molten thermoelectric-material may include contacting the molten thermoelectric-material with the cooler. The molten thermoelectric material is rapidly and unidirectionally cooled and solidified, thereby forming small-sized crystal grains of thermoelectric material. The small-sized crystal grains of thermoelectric material may provide low heat conductivity that is advantageous to the thermoelectric element.

Preferably, each of the first and second types of molten thermoelectric-material may include a first element selected from the group consisting of Bi and Sb, and a second element selected from the group consisting of Te and Se.

Preferably, the mold may be made of a material selected from the group consisting of alumina, calcium silicate and aluminum nitride. Calcium silicate may be expressed in a general formula mCaO.nSiO₂.xH₂O (x□0) such as xonotlite and tobamolite.

Preferably, the plurality of holes of the mold may include first and second sub-pluralities of holes. In this case, introducing the molten thermoelectric-material may include placing a first mask on the mold so that the first mask covers the second sub-plurality of holes, introducing the first type of molten thermoelectric material into the first sub-plurality of holes, removing the first mask from the mold, placing a second mask on the mold so that the second mask covers the first sub-plurality of holes, and introducing the second type of molten thermoelectric material into the second sub-plurality of holes. Solidifying the molten thermoelectric-material may include solidifying the first type of molten thermoelectric material in the first sub-plurality of holes, and solidifying the second type of molten thermoelectric material in the second sub-plurality of holes.

In accordance with a third aspect of the present invention, a method of forming a thermoelectric module may include placing a first mold that has a first plurality of holes at a position adjacent to a cooler, introducing a first type of molten thermoelectric material in the first plurality of holes of the mold adjacent to the cooler so that the first plurality of holes is filled with the first type of molten thermoelectric-material, solidifying the first type of molten thermoelectric-material in the first plurality of holes thereby forming first type thermoelectric elements in the first plurality of holes, placing a second mold that has a second plurality of holes at the position adjacent to the cooler, introducing a second type of molten thermoelectric-material in the second plurality of holes so that the second plurality of holes is filled with the second type of molten thermoelectric-material, solidifying the second type of molten thermoelectric-material in the second plurality of holes thereby forming second type thermoelectric elements in the second plurality of holes, placing the first type and second type thermoelectric elements on a first substrate that has a plurality of first electrodes so that two adjacent first type and second type thermoelectric elements of the first type and second type thermoelectric elements are in contact with one of the plurality of first electrodes, and placing a second substrate that has a plurality of second electrodes on the first type and second type thermoelectric elements placed on the first substrate so that the two adjacent first type and second type thermoelectric elements are in contact with two adjacent second electrodes of the plurality of second electrodes. The method of forming a thermoelectric module does not carry out wafer-slicing process or chip-dicing process, thereby reducing a manufacturing cost of the thermoelectric module. The method of forming a thermoelectric module does not use any jig or gadget to dispose an array of thermoelectric elements between the first and second substrates, thereby further reducing the manufacturing cost of the thermoelectric module.

Preferably, solidifying the molten thermoelectric-material may include thermally engaging the molten thermoelectric-material with the cooler.

Preferably, the plurality of holes may include a plurality of through holes. In this case, placing the mold may include placing the mold in contact with the cooler. Thermally engaging the molten thermoelectric-material may include contacting the molten thermoelectric-material with the cooler. The molten thermoelectric material is rapidly and unidirectionally cooled and solidified, thereby forming small-sized crystal grains of thermoelectric material. The small-sized crystal grains of thermoelectric material may provide low heat conductivity that is advantageous to the thermoelectric element.

Preferably, solidifying the molten thermoelectric-material may include unidirectionally solidifying the molten thermoelectric-material so that the plurality of thermoelectric elements includes a crystal structure that has a generally uniform crystal orientation

Preferably, each of the first and second types of molten thermoelectric-material may include a first element selected from the group consisting of Bi and Sb, and a second element selected from the group consisting of Te and Se.

Preferably, the mold may be made of a material selected from the group consisting of alumina, calcium silicate and aluminum nitride. Calcium silicate may be expressed in a general formula mCaO.nSiO₂.xH₂O (x□0) such as xonotlite and tobamolite.

In accordance with a fourth aspect of the present invention, a thermoelectric module may include a first substrate having a plurality of first electrodes, a second substrate having a plurality of second electrodes, and an array of first type and second type thermoelectric elements disposed between the first and second substrates. The first type and second type thermoelectric elements are connected between the plurality of first electrodes and the plurality of second electrodes. Two adjacent first type and second type thermoelectric elements of the first type and second type thermoelectric elements are in contact with one of the plurality of first electrodes. The two adjacent first type and second type thermoelectric elements are also in contact with two adjacent second electrodes of the plurality of second electrodes.

Preferably, each of the first and second types of molten thermoelectric-material may include a first element selected from the group consisting of Bi and Sb, and a second element selected from the group consisting of Te and Se.

Preferably, the first type and second type thermoelectric elements may include first type and second type thermoelectric materials solidified in holes of a mold. The first type and second type thermoelectric elements may be formed by the method described as the first aspect of the present invention.

Preferably, the mold may be made of a material selected from the group consisting of alumina, calcium silicate and aluminum nitride.

Selected embodiments of the present invention will now be described with reference to the drawings. It will be apparent to those skilled in the art from this disclosure that the following descriptions of the embodiments of the present invention are provided for illustration only and not for the purpose of limiting the invention as defined by the appended claims and their equivalents.

### FIRST EMBODIMENT

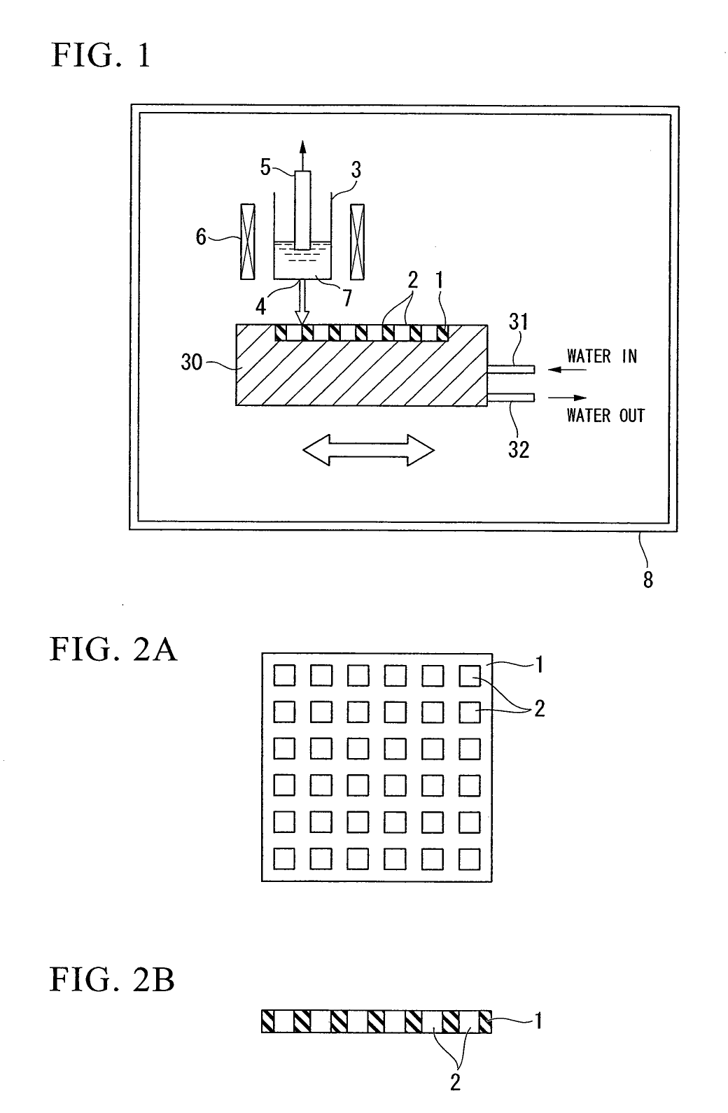

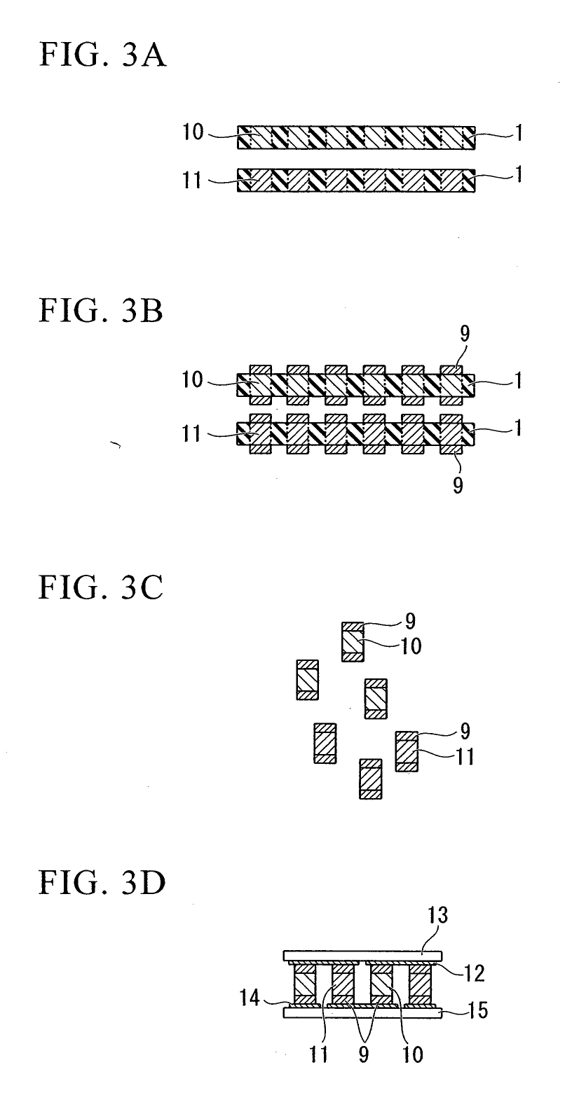

FIG. 1 is a schematic view illustrating an apparatus for preparing thermoelectric elements in accordance with a first embodiment of the present invention. FIG. 2A is a plan view illustrating a mold to be used for preparing thermoelectric elements in accordance with the first embodiment of the present invention. FIG. 2B is a cross sectional elevation view illustrating the mold shown in FIG. 2A. FIGS. 3A through 3B are cross sectional elevation views illustrating sequential steps involved in a method of forming a thermoelectric module in accordance with the first embodiment of the present invention.

As shown in FIG. 1, the apparatus for preparing thermoelectric elements may include, but is not limited to, a vacuum chamber 8, a cooling plate 30, and a container 3. The vacuum chamber 8 and the container 3 may be provided in the vacuum chamber 8. In general, the cooling plate 30 may be disposed in a position adjacent to the mold 1. The cooling plate 30 may be thermally engaged with the mold 1. In one case, the cooling plate 30 may be disposed as closely to the mold 1 as the cooling plate 30 is thermally engaged with the mold 1. In another case, the cooling plate 30 may be disposed in contact with the mold 1. In some case, the cooling plate 30 may have a cooling surface or cooling surfaces that is configured to be in contact with a mold 1 for cooling the mold 1. Particularly, the cooling plate 30 may have a non-flat surface that has a depressed portion configured to receive a mold 1. In other words, the depressed portion of the cooling plate 30 may be configured to engage with the mold 1. The mold 1 may have a plurality of holes 2 in which thermoelectric elements are defined or formed. In some case, the mold 1 may have a plurality of through holes 2. Typically, the mold 1 may have a matrix array of through holes 2 as shown in FIG. 2.

The cooling plate 30 may be configured to move in two-dimensional horizontal directions vertical to a upward or downward direction. In some case, the cooling plate 30 may be made of a highly heat conductive material such as copper. In some case, the cooling plate 30 may be configured to flow a cooling liquid such as cooling water therein. In this case, the cooling plate 30 may have an introduction port 31 and a discharge port 32. The introduction port 31 allows the cooling liquid or cooling water to be introduced into the cooling plate 30. The cooling plate 30 has a flow path that permits the flow of the cooling liquid or water. The flow path communicates between the introduction port 31 and the discharge port 32. The discharge port 32 allows the cooling liquid or water to be discharge from the cooling plate 30.

The container 3 is positioned over the mold 1 received in the depressed portion of the cooling plate 30. The container 3 is distanced from the mold 1. In some cases, the container 3 may be made of quartz. The container 3 is configured to contain a molten material 7. The container 3 may have a bottom wall with an injection hole 4 that allows the molten material 7 to drop through the injection hole 4 into the through hole 2 that is positioned under the injection hole 4. Processes for injecting the molten material 7 into all of the through holes 2 of the mold 1 are accomplished by moving the cooling plate 30 in the two-dimensional horizontal directions.

A stopper 5 may further be provided, which is configured to open and close the injection hole 4 to control the injection of the molten material 7. In some case, the stopper 5 may be configured to move in the elevational direction. The stopper 5 does down and the bottom of the stopper 5 is made into contact with the injection hole 4, thereby closing the injection hole 4 and stopping the drop of the molten material 7. The stopper 5 does up and the bottom of the stopper 5 is departed from the injection mole 4, thereby opening the injection hole 4 and allowing the drop of the molten material 7.

A heater 6 may also be provided around or in the vicinity of the container 3 to heat up the molten material 7 in the container 3.

The above described apparatus may be used to form the thermoelectric elements. The stopper 5 is moved downwardly so that the bottom of the stopper 5 is made into contact with the injection hole 4, thereby closing the injection hole 4. An ingot of thermoelectric material is put in the container 3. The existent gas in the vacuum chamber 8 is then vacuumed or replaced with an argon gas.

The heater 6 is operated to heat the container 3 so as to melt the ingot of thermoelectric material and prepare a molten thermoelectric material 7 in the container 3. Then, the stopper 5 moves upwardly to open the injection hole 4 thereby allowing the molten thermoelectric material 7 to drop from the injection hole 4 so that the molten thermoelectric material 7 is injected into the through holes 2 of the mold 1.

It is possible as a modification to put a molten thermoelectric material into the container 3. The molten thermoelectric material has a predetermined composition or compositional ratio. In this case, the heater 6 may be omitted.

It is also possible as a further modification to weight powders or particles of thermoelectric material so that the powders or particles of thermoelectric material to have a predetermined composition or compositional ratio. The weighted powders or particles of thermoelectric material are then put in the container 3 so that the heater 6 is used to heat the container 3 so as to melt the powders or particles of thermoelectric material and prepare the molten thermoelectric material 7 in the container 3.

As shown in FIG. 3A, the mold 1 with the through holes 2 is placed on the cooling plate 30. A p-type of molten thermoelectric material 7 is introduced into all of the through holes 2 thereby solidifying the p-type of molten thermoelectric material 7 in the through holes 2 so that p-type thermoelectric elements 10 are formed in the through holes 2 of the mold 1. The used mold 1 containing the p-type thermoelectric elements 10 is moved from the cooling plate 30. An additional mold 1 with through holes 2 is then placed on the cooling plate 30. An n-type of molten thermoelectric material 7 is introduced into all of the through holes 2 thereby solidifying the n-type of molten thermoelectric material 7 in the through holes 2 so that n-type thermoelectric elements 11 are formed in the through holes 2 of the mold 1. The used mold 1 containing the n-type thermoelectric elements 11 is moved from the cooling plate 30.

As shown in FIG. 3B, plated films 9 are formed on the surfaces of the p-type and n-type thermoelectric elements 10 and 11 by a plating process. A typical example of material for the plated films 9 may include, but is not limited to, nickel.

As shown in FIG. 3C, the p-type and n-type thermoelectric elements 10 and 11 are released from the mold 1.

As shown in FIG. 3D, a first substrate 15 that has an array of first electrodes 14 is prepared. A second substrate 13 that has an array of second electrodes 12 is also prepared. The p-type and n-type thermoelectric elements 10 and 11 are disposed on the array of first electrodes 14 of the first substrate 15 so that two closely adjacent p-type and n-type thermoelectric elements 10 and 11 are connected to one first electrode 14. The p-type and n-type thermoelectric elements 10 and 11 are bonded to the first electrodes 14 by soldering process. The two closely adjacent p-type and n-type thermoelectric elements 10 and 11 are electrically connected through the one first electrode 14 to each other. The second substrate 13 is placed on the p-type and n-type thermoelectric elements 10 and 11 that are disposed on the first substrate 15 so that the two adjacent p-type and n-type thermoelectric elements 10 and 11, which are connected to the one first electrode 14, are also connected to two adjacent second electrodes 12 of the second substrate 13. A series connection of alternating p-type and n-type thermoelectric elements 10 and 11 through the first and second electrodes 14 and 12 is formed between the first and second substrates 15 and 14.

### SECOND EMBODIMENT

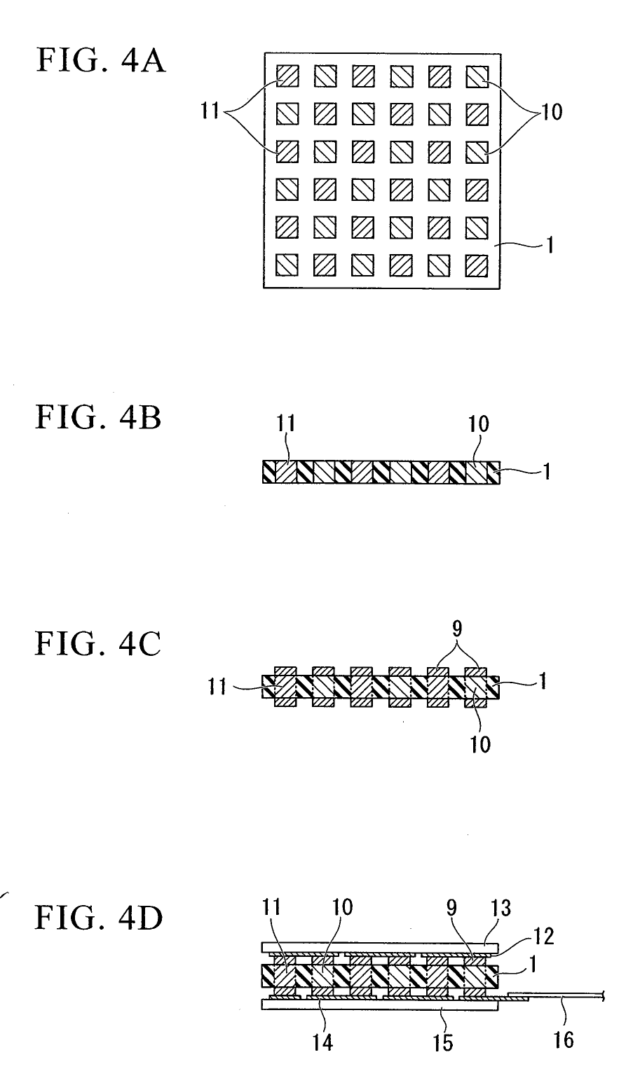

FIG. 4A is a plan view illustrating a step involved in a method of forming a thermoelectric module in accordance with a second embodiment of the present invention. FIG. 4B is a cross sectional elevation view illustrating the step shown in FIG. 4A. FIGS. 4C and 4D are cross sectional elevation views illustrating subsequent sequential steps involved in a method of forming a thermoelectric module in accordance with a second embodiment of the present invention.

As shown in FIGS. 4A and 4B, the mold 1 with the through holes 2 is placed on the cooling plate 30. The through holes 2 are classified into first-type through holes 2 and second-type through holes 2. The first type through holes 2 are used for forming first type thermoelectric elements. The second type through holes 2 are used for forming second type thermoelectric elements. The first-type through holes 2 are adjacent to the second-type through holes 2. Namely, two adjacent through holes 2 are the first type and second type through holes 2.

A first mask pattern is placed on the mold 1 so that the first mask pattern covers the second-type through holes 2 but does not cover the first-type through holes 2. A p-type molten thermoelectric material 7 is introduced into all of the first-type through holes 2, while the first mask pattern covers the second-type through holes 2, thereby solidifying the p-type molten thermoelectric material 7 in the first-type through holes 2 so that p-type thermoelectric elements 10 are formed in the first-type through holes 2 of the mold 1.

The used first mask pattern is removed from the mold 1. Then, a second mask pattern is placed on the mold 1 so that the second mask pattern covers the first-type through holes 2, in which the p-type thermoelectric elements 10 are present, but does not cover the second-type through holes 2. An n-type molten thermoelectric material 7 is introduced into all of the second-type through holes 2, while the second mask pattern covers the first-type through holes 2, thereby solidifying the n-type molten thermoelectric material 7 in the second-type through holes 2 so that n-type thermoelectric elements 11 are formed in the second-type through holes 2 of the mold 1. The used second mask pattern is removed from the mold 1.

The p-type and n-type thermoelectric elements 10 and 11 are formed in the plurality of through holes 2. Two adjacent thermoelectric elements are p-type and n-type thermoelectric elements 10 and 11. The used mold 1 containing the p-type and n-type thermoelectric elements 10 and 11 is moved from the cooling plate 30.

As shown in FIG. 4C, plated films 9 are formed on the surfaces of the p-type and n-type thermoelectric elements 10 and 11 by a plating process. A typical example of material for the plated films 9 may include, but is not limited to, nickel.

As shown in FIG. 4D, a first substrate 15 that has an array of first electrodes 14 is prepared. A second substrate 13 that has an array of second electrodes 12 is also prepared. The mold 1 with the p-type and n-type thermoelectric elements 10 and 11 is disposed on the first substrate 15 so that two closely adjacent p-type and n-type thermoelectric elements 10 and 11 are connected to one first electrode 14 of the first substrate 15. The p-type and n-type thermoelectric elements 10 and 11 are bonded to the first electrodes 14 by soldering process. The two closely adjacent p-type and n-type thermoelectric elements 10 and 11 are electrically connected through the one first electrode 14 to each other. The second substrate 13 is placed on the mold 1 having the p-type and n-type thermoelectric elements 10 and 11 that are disposed on the first substrate 15 so that the two adjacent p-type and n-type thermoelectric elements 10 and 11, which are connected to the one first electrode 14, are also connected to two adjacent second electrodes 12 of the second substrate 13. A series connection of alternating p-type and n-type thermoelectric elements 10 and 11 through the first and second electrodes 14 and 12 is formed between the first and second substrates 15 and 14, thereby forming a thermoelectric module.

A lead 16 is bonded to the first electrode 14 so that electromotive force generated by the thermoelectric elements 10 and 11 can be fetched through the lead 16.

Modifications:

A typical example of the shape of the through holes 2 may be a square as shown in FIGS. 2A and 4A. It is possible as a modification that the shape may be rectangle, other polygons, or circle. The square or rectangular shape of the through holes 2 makes it easy to mount the square or rectangular shape thermoelectric elements on the electrodes. The corners of the square or rectangular shape thermoelectric elements may be deformed. The circular or oval shape of the through holes 2 makes it easy to ensure the deformation-free shape of the thermoelectric elements but is not so suitable for mounting the thermoelectric elements on the electrodes.

Typical examples of the material for the mold 1 may include, but are not limited to, alumina, calcium silicate, and aluminum nitride. Calcium silicate may be expressed in a general formula mCaO.nSiO₂.xH₂O (x□0) such as xonotlite and tobamolite. The use of calcium silicate for the mold 1 may provide the following advantages.

In general, calcium silicate has a low heat conductivity in the range of 0.09 W/mK to 0.2 W/mk, and is fragile. This, the use of calcium silicate for the mold 1 makes it easy to release the thermoelectric elements from the holes 2. The fragility of calcium silicate makes it easy to break the mold 1 and then re-use the same forming a new mold. The use of calcium silicate may reduce the manufacturing cost. The low heat conductivity of calcium silicate may contribute to inhibit heat conduction from the molten thermoelectric material 7 to the mold 1, while the bottom of the mold 1 being adjacent to the cooling plate 30, thereby promoting a heat conduction from the molten thermoelectric material 7 to the cooling plate 30. Thus, the heat conduction from the molten thermoelectric material 7 to the cooling plate 30 dominates the other heat conduction from the molten thermoelectric material 7 to the mold 1. This means that the molten thermoelectric material 7 is cooled and solidified rapidly and almost unidirectionally. The rapid and almost unidirectional cooling and solidifying process may uniform a crystal orientation of the thermoelectric material 7, thereby preparing a solid thermoelectric material that has a low electric resistance. This improves the electric performance of the thermoelectric elements. Alumina and aluminum nitride are easily available and have high strengths.

The existent gas of the vacuum chamber 8 is vacuumed or substituted with an argon gas. If the existent gas of the vacuum chamber 8 is vacuumed, then this may prevent generation of foams in the molten thermoelectric material 7. No foam generation may provide a high mold-fillability of the molten thermoelectric material 7 in the holes 2 of the mold 1. Some element having high vapor pressure of the thermoelectric material may be likely to be vaporized. If the existent gas of the vacuum chamber 8 is substituted with an argon gas, then the argon gas suppresses the vaporization of elements of the thermoelectric material, thereby stabilizing the compositional ratio of the thermoelectric material under the high temperature condition. The substituted argon gas may allow generation of foams in the molten thermoelectric material. The foams may make it not easy to ensure a desired high fillability of the molten thermoelectric material.

### EXAMPLE 1

The thermoelectric module was prepared in the method described above with reference to FIGS. 3A through 3D. The mold 1 was prepared, which is made of calcium silicate, for example, xonotlite. The mold 1 have outer dimensions of 40 mm×40 mm in horizontal dimensions and 3.0 mm in thickness. The mold 1 has a matrix array (15×16=240) of square through holes 2 with sides of 1.5 mm. Namely, the mold 1 has 120 pairs of through holes 2. The thickness of the mold 1 is designed to be greater by 0.5 mm than an intended thickness of the thermoelectric elements so as to allow opposite surfaces of each of the thermoelectric elements to be polished. The matrix array was adjusted to that of a Peltier module.

The mold 1 was placed in the depressed portion of the cooling plate 30 in the vacuum chamber 8. The mold 1 was then held by a holder to prevent the mold 1 from moving in the process for introducing the molten thermoelectric material into the holes 2 of the mold 1.

A p-type thermoelectric material of Bi_{0.5}Sb_{1.5}Te₃ was prepared by weighting Bi, Sb and Te. A total amount of the p-type thermoelectric material was determined so that the molten thermoelectric materials will be filled up the holes 2 and slightly overflowed from them. A quartz crucible was used as the container 3. The quartz crucible as the container 3 has a bottom with an injection hole 4 that has dimensions of 0.5 mm in width and 40 mm in length. The quartz crucible as the container 3 also has a thermocouple that monitors the temperature of the p-type thermoelectric material.

The p-type thermoelectric material was put in the container 3, while the stopper 5 made of alumina closes the injection hole 4. The container 3 is placed in the vacuum chamber 8 so that the container 3 is positioned over the mold 1.

The vacuum chamber 8 was vacuumed at a degree of vacuum of at most 1E-1 Pa. An electrical power was supplied to the heater 6 so that the heater 6 heats up the p-type thermoelectric material in the container 3, thereby preparing a molten p-type thermoelectric material in the container 3. The heater 6 further heated the molten p-type thermoelectric material so that the temperature of the p-type thermoelectric material was increased to 750□, and then the temperature was maintained at that temperature for 1 minute.

The stopper 5 was moved upwardly so as to open the injection hole 4 to allow the molten p-type thermoelectric material to drop through the injection hole 4 onto the holes 2 of the mold 1, while the cooling plate 30 on which the mold 1 is mounted was moved in a horizontal direction perpendicular to the longitudinal direction of the injection hole 4. The through holes 2 of the mold 1 were filled up with the molten p-type thermoelectric material. The moving speed of the cooling plate 30 was decided as that each of the through holes 2 is filled up and also slightly overflowed with the molten p-type thermoelectric material. The cooling plate 30 was moved in the range of 1 cm/sec to 3 cm/sec. The overflowed molten p-type thermoelectric material was dropped to a molten pool that is provided around the cooling plate 30. Since the mold 1 was in contact with the cooling plate 30, and then the molten p-type thermoelectric material in the through holes 2 of the mold 1 was cooled and solidified rapidly and unidirectionally so as to crystallize the p-type thermoelectric material, thereby obtaining the p-type thermoelectric elements 10 in the through holes 2 of the mold 1.

The vacuum of the vacuum chamber 8 was broken. The mold 1 was then picked up from the vacuum chamber 8. A polishing process was carried out to polish the surfaces of the mold 1 and the surfaces of the p-type thermoelectric elements 10 so that the height of the p-type thermoelectric elements 10 is reduced to 2.5 mm. The foregoing processes correspond to the step 1 shown in FIG. 3A.

Nickel layers were formed on the opposite surfaces of each of the p-type thermoelectric elements 10 by a known electroless plating process. The p-type thermoelectric elements 10 were then released from the mold 1. Releasing the p-type thermoelectric elements 10 from the mold 1 can be performed by utilizing heat shrinkage of the p-type thermoelectric elements 10 themselves. If the heat shrinkage is insufficient to release the p-type thermoelectric elements 10 from the mold 1, then it is possible to break the mold 1 to release the p-type thermoelectric elements 10 because the mold 1 is fragile.

An n-type thermoelectric material of Bi_{1.9}Sb_{0.1}Te_{2.7}Se_{0.3} was prepared by weighting Bi, Sb, Te and Se. In the same manners as the p-type thermoelectric elements 10, n-type thermoelectric elements 11 were prepared.

The first substrate 15 was prepared which has a matrix array of first electrodes 14. The second substrate 13 was also prepared which has another matrix array of second electrodes 12. The first and second substrates 15 and 13 are made of alumina.

The p-type thermoelectric elements 10 and the n-type thermoelectric elements 11 were disposed on the matrix array of the first electrodes 14 of the first substrate 15 so that two adjacent p-type and n-type thermoelectric elements 10 and 11 are disposed on each of the first electrodes 14. The two adjacent p-type and n-type thermoelectric elements 10 and 11 are distanced from each other by a gap. The two adjacent p-type and n-type thermoelectric elements 10 and 11 were bonded to each of the first electrodes 14 by soldering process so that the two adjacent p-type and n-type thermoelectric elements 10 and 11 were electrically connected to each other through the first electrode 14.

The second substrate 13 was disposed over the matrix array of p-type and n-type thermoelectric elements 10 and 11 bonded on the matrix array of the first electrodes 14 of the first substrate 15, so that the two adjacent p-type and n-type thermoelectric elements 10 and 11, which are electrically connected to each of the first electrodes 14, were also in contact with two adjacent second electrodes 12. The two adjacent p-type and n-type thermoelectric elements 10 and 11 were bonded to the two adjacent second electrodes 12 by soldering process so that the two adjacent p-type and n-type thermoelectric elements 10 and 11 are electrically connected to the two adjacent second electrodes 12. The two adjacent second electrodes 12 were electrically connected to each other through the two adjacent p-type and n-type thermoelectric elements 10 and 11 and the first electrode 14. The alternate cascade connection of the p-type and n-type thermoelectric elements 10 and 11 was formed between the first and second substrates 15 and 13. In other words, the alternate series connection of the p-type and n-type thermoelectric elements 10 and 11 was formed between the first and second substrates 15 and 13. As a result, the thermoelectric module was completed. The thermoelectric module was of Peltier module.

The thermoelectric module was prepared without carrying out wafer-slicing process and dicing processes, thereby reducing the manufacturing cost by 15 percents.

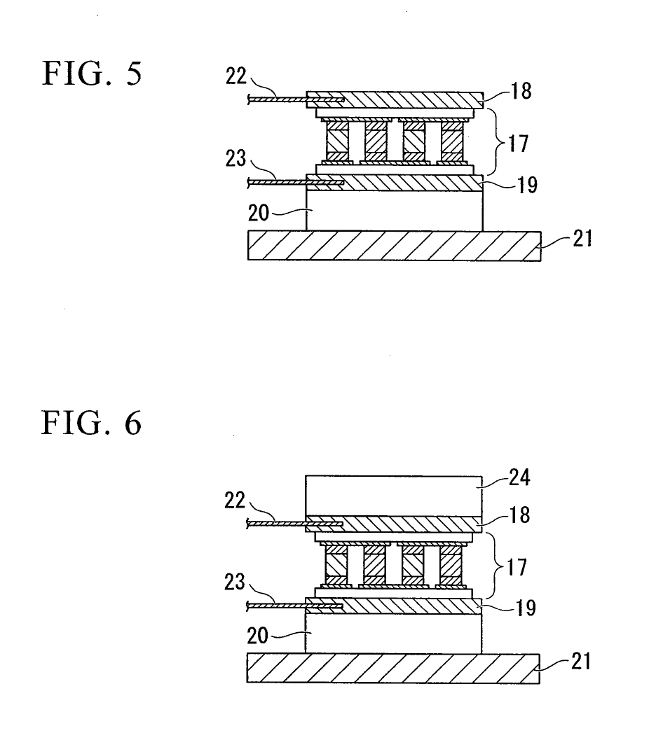

The performances of the thermoelectric module were evaluated as follows. FIG. 5 is a cross sectional elevation view illustrating the thermoelectric module to be measured in thermoelectric conversion efficiency. A Peltier module 17 as the thermoelectric module was subject to the measurement of thermoelectric conversion efficiency. The Peltier module 17 was sandwiched between two copper plates 18 and 19. The Peltier module 17 with the two copper plates 18 and 19 was mounted on a temperature-controlling Peltier module 20 disposed on a heat sink 21 as a heat radiator.

The copper plate 18 is in contact with the second substrate of the Peltier module 17. The copper plate 18 has a first thermocouple 22 that is adapted to measure a first temperature Tc of the lower temperature side of the Peltier module 17. The other copper plate 19 is in contact with the first substrate of the Peltier module 17. The copper plate 19 has a second thermocouple 23 that is adapted to measure a second temperature Th of the high temperature side of the Peltier module 17.

The temperature-controlling Peltier module 20 was operated to maintain an indicated value Th at 100□ of the second thermocouple 23, while applying a current to the Peltier module 17 subject to the measurement so that another indicated value Tc of the first thermocouple 22 was measured. A temperature differenceΔT is defined to be ΔT=Th−Tc. The maximum value of the temperature differenceΔT is defined to a measured result. Increasing the temperature difference between the first and second sides of the thermoelectric module causes increased electricity that is generated by the thermoelectric module. If the maximum of the temperature differenceΔT as the measured result is high, then this means that the thermoelectric conversion efficiency is high.

FIG. 6 is a cross sectional elevation view illustrating the thermoelectric module to be measured in maximum endothermic quantity. A Peltier module 17 as the thermoelectric module was subject to the measurement of thermoelectric conversion efficiency. The Peltier module 17 was sandwiched between two copper plates 18 and 19. The Peltier module 17 with the two copper plates 18 and 19 was mounted on a temperature-controlling Peltier module 20 disposed on a heat sink 21 as a heat radiator.

The copper plate 18 is in contact with the second substrate of the Peltier module 17. The copper plate 18 has a first thermocouple 22 that is adapted to measure a first temperature Tc of the lower temperature side of the Peltier module 17. The other copper plate 19 is in contact with the first substrate of the Peltier module 17. The copper plate 19 has a second thermocouple 23 that is adapted to measure a second temperature Th of the high temperature side of the Peltier module 17. A heater 24 is placed on the copper plate 18.

An electrical power was applied to the heater 24 so as to heat up the cooper plate 18, thereby causing a temperature difference between the first and second sides of the Peltier module 17. The temperature difference causes a current flow through the Peltier module 17, while the temperature difference is reduced so that the first temperature Tc measured by the first thermocouple 22 becomes closer to the second temperature Th measured by the second thermocouple 23. The electrical power applied to the heater 24 was gradually increased to increase the current flow through the Peltier module 17 so that the first temperature Tc measured by the first thermocouple 22 becomes equal to the second temperature Th measured by the second thermocouple 23. The electrical power applied to the heater 24 was adjusted so that the first temperature Tc is maintained equal to the second temperature Th. The second temperature Th was controlled by the temperature-controlling Peltier module 20. Ordinary, the second temperature Th may, for example, be 27□. The Peltier module 17 shows the endothermic performance that maintains the first temperature Tc to be equal to the second temperature Th in an acceptable range of power of the heater 24. If the power of the heater 24 becomes beyond the upper limit of the acceptable range, then the first temperature Tc becomes different from the second temperature Th. In other words, the maximum endothermic quantity of the Peltier module 17 corresponds to the power applied to the heater 24 when the Peltier module 17 becomes incapable of maintaining the first temperature Tc to be equal to the second temperature Th. As the amount of heat transmitted through the thermoelectric module is large, the electricity generated by the thermoelectric module is also large. Thus, if the endothermic quantity of the heat source of the thermoelectric module is large, then this means that the thermoelectric conversion efficiency of the thermoelectric module is also high.

It was confirmed that the manufacturing cost was reduced by 15%. The performances of the thermoelectric module were measured in the above-described manners. It was confirmed that the thermoelectric module has the maximum temperature differenceΔT of 73K and the maximum endothermic quality of 140 W.

### EXAMPLE 2

The thermoelectric module was prepared in the method described above with reference to FIGS. 4A through 4D. As shown in FIGS. 4A and 4B, the mold 1 was prepared, which is made of calcium silicate, for example, xonotlite. The mold 1 have outer dimensions of 40 mm×40 mm in horizontal dimensions and 3.0 mm in thickness. The mold 1 has a matrix array (15×16=240) of square through holes 2 with sides of 1.5 mm. Namely, the mold 1 has 120 pairs of through holes 2. The thickness of the mold 1 is designed to be greater by 0.5 mm than an intended thickness of the thermoelectric elements so as to allow opposite surfaces of each of the thermoelectric elements to be polished. The matrix array was adjusted to that of a Peltier module. The mold 1 has the matrix array of through holes 2. The matrix array of through holes 2 corresponds to combined first and second sub-arrays of through holes 2. The first sub-array of through holes 2 is to form p-type thermoelectric elements 10. The second sub-array of through holes 2 is to form n-type thermoelectric elements 11.

A first mask pattern was prepared and was disposed on the mold 1. The first mask pattern has a first array of openings, each of which has sides of 2.0 mm. The first array of openings corresponds to the first sub-array of through holes 2 that is to form p-type thermoelectric elements 10. The first mask pattern covers the second sub-array of through holes 2 that is to form n-type thermoelectric elements 11. The first mask pattern has a thickness of 0.3 mm. The first mask pattern also has a peripheral portion having alignment projecting portions that align the first mask pattern to the mold 1.

The mold 1 with the first mask pattern was placed in the depressed portion of the cooling plate 30 in the vacuum chamber 8. The mold 1 with the first mask pattern was then held by a holder to prevent the mold 1 from moving in the process for introducing the molten thermoelectric material into the holes 2 of the mold 1.

A p-type thermoelectric material of Bi_{0.5}Sb_{1.5}Te₃ was prepared by weighting Bi, Sb and Te. The p-type thermoelectric material was put in the container 3, while the stopper 5 made of alumina closes the injection hole 4. The container 3 was placed in the vacuum chamber 8 so that the container 3 is positioned over the mold 1 with the first mask pattern.

The vacuum chamber 8 was vacuumed at a degree of vacuum of at most 1E-1 Pa. An electrical power was supplied to the heater 6 so that the heater 6 heats up the p-type thermoelectric material in the container 3, thereby preparing a molten p-type thermoelectric material in the container 3. The heater 6 further heated the molten p-type thermoelectric material so that the temperature of the p-type thermoelectric material was increased to 750□, and then the temperature was maintained at that temperature for 1 minute.

The stopper 5 was moved upwardly so as to open the injection hole 4 to allow the molten p-type thermoelectric material to drop through the injection hole 4 onto the first sub-array of through holes 2 of the mold 1 covered by the first mask pattern, while the cooling plate 30 on which the mold 1 is mounted was moved in a horizontal direction perpendicular to the longitudinal direction of the injection hole 4. The first sub-array of through holes 2 of the mold 1 covered by the first mask pattern was filled up with the molten p-type thermoelectric material. The moving speed of the cooling plate 30 was decided as that each of the first sub-array of through holes 2 is filled up and also slightly overflowed with the molten p-type thermoelectric material. The cooling plate 30 was moved in the range of 1 cm/sec to 3 cm/sec. The overflowed molten p-type thermoelectric material was dropped to a molten pool that is provided around the cooling plate 30. Since the mold 1 was in contact with the cooling plate 30, and then the molten p-type thermoelectric material in the first sub-array of through holes 2 of the mold 1 covered by the first mask pattern was cooled and solidified rapidly and unidirectionally so as to crystallize the p-type thermoelectric material, thereby obtaining the p-type thermoelectric elements 10 in the first sub-array of through holes 2 of the mold 1 covered by the first mask pattern.

The vacuum of the vacuum chamber 8 was broken. The mold 1 was then picked up from the vacuum chamber 8. The used first mask pattern was removed from the mold 1. A second mask pattern was further prepared and was disposed on the mold 1. The second mask pattern has a second array of openings, each of which has a diameter of 2.0 mm. The second array of openings corresponds to the second sub-array of through holes 2 that is to form n-type thermoelectric elements 11. The second mask pattern covers the first sub-array of through holes 2 that is to form p-type thermoelectric elements 10. The second mask pattern has a thickness of 0.3 mm. The second mask pattern also has a peripheral portion having alignment projecting portions that align the second mask pattern to the mold 1.

The mold 1 with the second mask pattern was placed in the depressed portion of the cooling plate 30 in the vacuum chamber 8. The mold 1 with the second mask pattern was then held by a holder to prevent the mold 1 from moving in the process for introducing the molten thermoelectric material into the holes 2 of the mold 1.

An n-type thermoelectric material of Bi_{1.9}Sb_{0.1}Te_{2.7}Se_{0.3} was prepared by weighting Bi, Sb, Te and Se. The n-type thermoelectric material was put in the container 3, while the stopper 5 made of alumina closes the injection hole 4. The container 3 was placed in the vacuum chamber 8 so that the container 3 is positioned over the mold 1 with the second mask pattern.

The vacuum chamber 8 was vacuumed at a degree of vacuum of at most 1E-1 Pa. An electrical power was supplied to the heater 6 so that the heater 6 heats up the n-type thermoelectric material in the container 3, thereby preparing a molten n-type thermoelectric material in the container 3. The heater 6 further heated the molten n-type thermoelectric material so that the temperature of the n-type thermoelectric material was increased to 750□, and then the temperature was maintained at that temperature for 1 minute.

The stopper 5 was moved upwardly so as to open the injection hole 4 to allow the molten n-type thermoelectric material to drop through the injection hole 4 onto the second sub-array of through holes 2 of the mold 1 covered by the second mask pattern, while the cooling plate 30 on which the mold 1 with the second mask pattern is mounted was moved in a horizontal direction perpendicular to the longitudinal direction of the injection hole 4. The second sub-array of through holes 2 of the mold 1 covered by the second mask pattern was filled up with the molten n-type thermoelectric material. The moving speed of the cooling plate 30 was decided as that each of the second sub-array of through holes 2 is filled up and also slightly overflowed with the molten n-type thermoelectric material. The cooling plate 30 was moved in the range of 1 cm/sec to 3 cm/sec. The overflowed molten n-type thermoelectric material was dropped to a molten pool that is provided around the cooling plate 30. Since the mold 1 was in contact with the cooling plate 30, and then the molten n-type thermoelectric material in the second sub-array of through holes 2 of the mold 1 covered by the second mask pattern was cooled and solidified rapidly and unidirectionally so as to crystallize the n-type thermoelectric material, thereby obtaining the n-type thermoelectric elements 11 in the second sub-array of through holes 2 of the mold 1 covered by the second mask pattern. The used second mask pattern was removed.

The p-type and n-type thermoelectric elements 10 and 11 were formed in the through holes 2 of the mold 1.

A polishing process was carried out to polish the surfaces of the mold 1 and the surfaces of the p-type and n-type thermoelectric elements 10 and 11 so that the height of the p-type and n-type thermoelectric elements 10 and 11 is reduced to 2.5 mm.

As shown in FIG. 4C, nickel layers were formed on the opposite surfaces of each of the p-type and n-type thermoelectric elements 10 and 11 by a known electroless plating process.

As shown in FIG. 4D, the first substrate 15 was prepared which has a matrix array of first electrodes 14. The second substrate 13 was also prepared which has another matrix array of second electrodes 12. The first and second substrates 15 and 13 are made of alumina.

The mold 1 having the p-type and n-type thermoelectric elements 10 and 11 were disposed on the matrix array of the first electrodes 14 of the first substrate 15 so that two adjacent p-type and n-type thermoelectric elements 10 and 11 are disposed on each of the first electrodes 14. The two adjacent p-type and n-type thermoelectric elements 10 and 11 are distanced from each other by a gap. The two adjacent p-type and n-type thermoelectric elements 10 and 11 were bonded to each of the first electrodes 14 by soldering process so that the two adjacent p-type and n-type thermoelectric elements 10 and 11 were electrically connected to each other through the first electrode 14.

The second substrate 13 was disposed over the mold 1 having the p-type and n-type thermoelectric elements 10 and 11 bonded on the matrix array of the first electrodes 14 of the first substrate 15, so that the two adjacent p-type and n-type thermoelectric elements 10 and 11, which are electrically connected to each of the first electrodes 14, were also in contact with two adjacent second electrodes 12. The two adjacent p-type and n-type thermoelectric elements 10 and 11 were bonded to the two adjacent second electrodes 12 by soldering process so that the two adjacent p-type and n-type thermoelectric elements 10 and 11 are electrically connected to the two adjacent second electrodes 12. The two adjacent second electrodes 12 were electrically connected to each other through the two adjacent p-type and n-type thermoelectric elements 10 and 11 and the first electrode 14. The alternate cascade connection of the p-type and n-type thermoelectric elements 10 and 11 was formed between the first and second substrates 15 and 13. In other words, the alternate series connection of the p-type and n-type thermoelectric elements 10 and 11 was formed between the first and second substrates 15 and 13. As a result, the thermoelectric module was completed. The thermoelectric module was of Peltier module.

The thermoelectric module was prepared without carrying out wafer-slicing process and dicing processes, thereby reducing the manufacturing cost by 25 percents.

The performances of the thermoelectric module were evaluated in the same manner as in Example 1. It was confirmed that the manufacturing cost was reduced by 25%. The performances of the thermoelectric module were measured in the above-described manners. It was confirmed that the thermoelectric module has the maximum temperature differenceΔT of 70K and the maximum endothermic quality of 155 W.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The term “configured” is used to describe a component, section or part of a device includes hardware and/or software that is constructed and/or programmed to carry out the desired function.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A method of forming thermoelectric elements, the method comprising:
introducing a molten thermoelectric-material in a plurality of holes of a mold; and
solidifying the molten thermoelectric-material in the plurality of holes, thereby forming a plurality of thermoelectric elements in the plurality of holes.

2. The method according to claim 1, further comprising:
cooling the mold before introducing the molten thermoelectric-material in the plurality of holes of the cooled mold.

3. The method according to claim 2, wherein cooling the mold comprises placing the mold at a position adjacent to a cooler, before introducing the molten thermoelectric material in the plurality of holes.

4. The method according to claim 3, wherein the plurality of holes comprise a plurality of through holes,
placing the mold comprises placing the mold in contact with the cooler; and
thermally engaging the molten thermoelectric-material with the cooler comprises contacting the molten thermoelectric-material with the cooler.

5. The method according to claim 1, wherein solidifying the molten thermoelectric-material comprises unidirectionally solidifying the molten thermoelectric-material so that the plurality of thermoelectric elements include a crystal structure that has a generally uniform crystal orientation.

6. The method according to claim 1, further comprising:
introducing a different molten thermoelectric-material in a plurality of different holes of a different mold; and
solidifying the different molten thermoelectric-material in the plurality of different holes of the different mold, thereby forming a plurality of different thermoelectric elements in the plurality of different holes of the different mold.

7. The method according to claim 1, wherein the plurality of holes of the mold comprises first and second sub-pluralities of holes, and the molten thermoelectric-material comprises first and second types of molten thermoelectric material, and
wherein introducing the molten thermoelectric-material comprises:
placing a first mask on the mold so that the first mask covers the second sub-plurality of holes;
introducing the first type of molten thermoelectric material into the first sub-plurality of holes;
removing the first mask from the mold;
placing a second mask on the mold so that the second mask covers the first sub-plurality of holes; and
introducing the second type of molten thermoelectric material into the second sub-plurality of holes, and
wherein solidifying the molten thermoelectric-material comprises:
solidifying the first type of molten thermoelectric material in the first sub-plurality of holes; and
solidifying the second type of molten thermoelectric material in the second sub-plurality of holes.

8. A method of forming a thermoelectric module, the method comprising:
placing a mold that has a plurality of holes at a position adjacent to a cooler;
introducing first and second types of molten thermoelectric-material in the plurality of holes of the mold adjacent to the cooler, so that a first one of the plurality of holes is filled with the first type of molten thermoelectric-material and a second one adjacent to the first one of the plurality of holes is filled with the second type of molten thermoelectric-material;
solidifying the first and second types of molten thermoelectric-material in the plurality of holes, thereby forming first type and second type thermoelectric elements in the plurality of holes;
placing the mold having the first type and second type thermoelectric elements on a first substrate that has a plurality of first electrodes so that two adjacent first type and second type thermoelectric elements of the first type and second type thermoelectric elements are in contact with one of the plurality of first electrodes; and
placing a second substrate that has a plurality of second electrodes on the first type and second type thermoelectric elements placed on the first substrate so that the two adjacent first type and second type thermoelectric elements are in contact with two adjacent second electrodes of the plurality of second electrodes.

9. The method according to claim 8, wherein solidifying the molten thermoelectric-material comprises thermally engaging the molten thermoelectric-material with the cooler.

10. The method according to claim 9, wherein the plurality of holes comprise a plurality of through holes,
placing the mold comprises placing the mold in contact with the cooler; and
thermally engaging the molten thermoelectric-material comprises contacting the molten thermoelectric-material with the cooler.

11. The method according to claim 8, wherein solidifying the molten thermoelectric-material comprises unidirectionally solidifying the molten thermoelectric-material so that the plurality of thermoelectric elements include a crystal structure that has a generally uniform crystal orientation.

12. The method according to claim 8, wherein each of the first and second types of molten thermoelectric-material comprises a first element selected from the group consisting of Bi and Sb, and a second element selected from the group consisting of Te and Se.

13. The method according to claim 8, wherein the mold is made of a material selected from the group consisting of alumina, calcium silicate and aluminum nitride.

14. The method according to claim 8, wherein the plurality of holes of the mold comprises first and second sub-pluralities of holes, and
wherein introducing the molten thermoelectric-material comprises:
placing a first mask on the mold so that the first mask covers the second sub-plurality of holes;
introducing the first type of molten thermoelectric material into the first sub-plurality of holes;
removing the first mask from the mold;
placing a second mask on the mold so that the second mask covers the first sub-plurality of holes; and
introducing the second type of molten thermoelectric material into the second sub-plurality of holes, and
wherein solidifying the molten thermoelectric-material comprises:
solidifying the first type of molten thermoelectric material in the first sub-plurality of holes; and
solidifying the second type of molten thermoelectric material in the second sub-plurality of holes.

15. A method of forming a thermoelectric module, the method comprising:
placing a first mold that has a first plurality of holes at a position adjacent to a cooler;
introducing a first type of molten thermoelectric-material in the first plurality of holes of the mold adjacent to the cooler, so that the first plurality of holes is filled with the first type of molten thermoelectric-material;
solidifying the first type of molten thermoelectric-material in the first plurality of holes, thereby forming first type thermoelectric elements in the first plurality of holes;
placing a second mold that has a second plurality of holes at the position adjacent to the cooler;
introducing a second type of molten thermoelectric-material in the second plurality of holes, so that the second plurality of holes is filled with the second type of molten thermoelectric-material;
solidifying the second type of molten thermoelectric-material in the second plurality of holes, thereby forming second type thermoelectric elements in the second plurality of holes;
placing the first type and second type thermoelectric elements on a first substrate that has a plurality of first electrodes so that two adjacent first type and second type thermoelectric elements of the first type and second type thermoelectric elements are in contact with one of the plurality of first electrodes; and
placing a second substrate that has a plurality of second electrodes on the first type and second type thermoelectric elements placed on the first substrate so that the two adjacent first type and second type thermoelectric elements are in contact with two adjacent second electrodes of the plurality of second electrodes.

16. The method according to claim 15, wherein solidifying the molten thermoelectric-material comprises thermally engaging the molten thermoelectric-material with the cooler.

17. The method according to claim 16, wherein the plurality of holes comprise a plurality of through holes,
placing the mold comprises placing the mold in contact with the cooler; and
thermally engaging the molten thermoelectric-material comprises contacting the molten thermoelectric-material with the cooler.

18. The method according to claim 15, wherein solidifying the molten thermoelectric-material comprises unidirectionally solidifying the molten thermoelectric-material so that the plurality of thermoelectric elements include a crystal structure that has a generally uniform crystal orientation.

19. The method according to claim 15, wherein each of the first and second types of molten thermoelectric-material comprises a first element selected from the group consisting of Bi and Sb, and a second element selected from the group consisting of Te and Se.

20. The method according to claim 15, wherein the mold is made of a material selected from the group consisting of alumina, calcium silicate and aluminum nitride.

21. A thermoelectric module comprising:
a first substrate having a plurality of first electrodes;
a second substrate having a plurality of second electrodes; and
an array of first type and second type thermoelectric elements disposed between the first and second substrates, the first type and second type thermoelectric elements being connected between the plurality of first electrodes and the plurality of second electrodes,
wherein two adjacent first type and second type thermoelectric elements of the first type and second type thermoelectric elements are in contact with one of the plurality of first electrodes, and
the two adjacent first type and second type thermoelectric elements are in contact with two adjacent second electrodes of the plurality of second electrodes.

22. The thermoelectric module according to claim 21, wherein each of the first and second types of molten thermoelectric-material comprises a first element selected from the group consisting of Bi and Sb, and a second element selected from the group consisting of Te and Se.

23. The thermoelectric module according to claim 22, wherein the mold is made of a material selected from the group consisting of alumina, calcium silicate and aluminum nitride.

24. The thermoelectric module according to claim 21, wherein the first type and second type thermoelectric elements comprise first type and second type thermoelectric materials solidified in holes of a mold.
